(19) United States
(12) Patent Application Publication
(10) Pub. No.: US 2021/0007245 A1
(43) Pub. Date: Jan. 7, 2021

(54) HEAT DISSIPATION DEVICE

(71) Applicant: GIGA-BYTE TECHNOLOGY CO.,LTD., New Taipei City (TW)

(72) Inventors: Shun-Chih Huang, New Taipei City (TW); Tai-Chuan Mao, New Taipei City (TW); Chun-Liang Guo, New Taipei City (TW)

(73) Assignee: GIGA-BYTE TECHNOLOGY CO.,LTD., New Taipei City (TW)

(21) Appl. No.: 16/904,573

(22) Filed: Jun. 18, 2020

(30) Foreign Application Priority Data
Jul. 3, 2019 (TW) 108208638

(51) Int. Cl. H05K 7/20

(52) U.S. Cl. CPC H05K 7/20272; H05K 7/20336; H05K 7/20254

(57) ABSTRACT

A heat dissipation device is adapted to be disposed on a primary heat source and a secondary heat source. The heat dissipation device includes a water cooling head module and a heat conducting member. The water cooling head module is disposed on the primary heat source. The heat conducting member is thermally coupled to the secondary heat source and extends into the water cooling head module.

### CROSS-REFERENCE TO RELATED APPLICATION

This application claims the priority benefit of Taiwan patent application serial no. 108208638, filed on Jul. 3, 2019. The entirety of each of the above-mentioned patent applications is hereby incorporated by reference and made a part of this specification.

### BACKGROUND

### Technical Field

The disclosure relates to a heat dissipation device, and in particular to a heat dissipation device capable of dissipating heat from a plurality of heat sources.

### Description of Related Art

In general, a water cooling head heat dissipation device is often disposed on a circuit board to dissipate heat from a heat source on the circuit board. The common water cooling head heat dissipation devices may be categorized into closed water cooling structures and open water cooling structures; in either structure, a part of the water cooling head heat dissipation device is usually thermally coupled to the heat source, and the heat of the heat source is transmitted to heat dissipation fins through liquid, so as to dissipate the heat energy.

Nowadays, computer devices have been developed to achieve high performance and occupy small size, and there are usually plural heat sources on a circuit board. In view of the above, how to dissipate heat from plural heat sources simultaneously and improve the overall heat dissipation effects with use of a simple device occupying small space has become an issue that requires prompt resolution.

### SUMMARY

The disclosure provides a heat dissipation device capable of dissipating heat from plural heat sources.

The heat dissipation device provided in an embodiment of the disclosure is adapted to be disposed on a primary heat source and a secondary heat source. The heat dissipation device includes a water cooling head module and a heat conducting member. The water cooling head module is disposed on the primary heat source. The heat conducting member is thermally coupled to the secondary heat source and extends into the water cooling head module.

In an embodiment of the disclosure, the water cooling head module has a water cooling tank and a plurality of fins. The fins extend along a first direction and are arranged in parallel along a second direction in the water cooling tank. The fins sleeve on one portion of the heat conducting member in the second direction.

In an embodiment of the disclosure, the heat conducting member includes a heat pipe.

In an embodiment of the disclosure, the water cooling head module has a water cooling tank, a water inlet, a water outlet, and a plurality of fins. The water inlet and the water outlet respectively communicate with the water cooling tank. The fins extend along the first direction and are arranged in parallel along the second direction in the water cooling tank. The water cooling head module includes at least one side wall and at least one inner partition board. The at least one side wall extends along the first direction and is located on at least one side of fin, and the at least one inner partition board extends along the second direction and is connected to the at least one side wall and at least one outermost fin of the fins.

In an embodiment of the disclosure, the at least one side wall includes two side walls, and the at least one inner partition board includes two inner partition boards. The two side walls extend along the first direction and are located at both sides of the fins, and the two inner partition boards extend along the second direction and are connected to two outermost fins of the fins. The water inlet is located at one side of a line connecting the two side walls, and the water outlet is located at the other side of the line connecting the two side walls.

In an embodiment of the disclosure, the water cooling head module has a water cooling tank, a water inlet, a water outlet, and a plurality of fins. The water cooling tank includes a first region and a second region. The water inlet is connected to the first region, and the water outlet is connected to the second region. The fins extend from the first region to the second region. The heat conducting member has a first terminal, a second terminal opposite to the first terminal, and a middle segment located between the first terminal and the second terminal. The middle segment is thermally coupled to the secondary heat source, the first terminal extends into and communicates with the first region of the water cooling tank, and the second terminal extends into and communicates with the second region of the water cooling tank.

In an embodiment of the disclosure, the heat conducting member is a runner pipe, and an inner diameter of the first terminal of the runner pipe is greater than an inner diameter of the second terminal.

In an embodiment of the disclosure, the heat dissipation device further includes a heat sink disposed on the secondary heat source, and the heat conducting member is thermally coupled to the secondary heat source through the heat sink.

In an embodiment of the disclosure, the water cooling head module further includes a bottom plate disposed on the primary heat source, and the heat conducting member contacts the bottom plate.

In an embodiment of the disclosure, the water cooling head module further includes a bottom plate disposed on the primary heat source, and the heat conducting member is suspended from the bottom plate.

Based on the above, the heat dissipation device provided in one or more embodiments of the disclosure includes the water cooling head module and the heat conducting member. The water cooling head module is thermally coupled to the primary heat source, one portion of the heat conducting member extends into the water cooling head module, and the other portion is thermally coupled to the secondary heat source. Thereby, the heat dissipation device provided in one or more embodiments of the disclosure dissipates heat from plural heat sources at the same time with use of one water cooling head module. In other words, the heat dissipation device provided in one or more embodiments of the disclosure may achieve heat dissipation effects within a limited space in a more efficient manner and may be more extensively applied.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a schematic assembly view illustrating that a heat dissipation device disposed on a circuit board according to an embodiment of the disclosure.

FIG. 1B is a schematic top view illustrating that the heat dissipation device in FIG. 1A is disposed on a circuit board.

FIG. 1C is a schematic view illustrating that the heat dissipation device in FIG. 1A is disposed on a circuit board at another view angle.

FIG. 1D is a schematic partial cross-sectional view illustrating that the heat dissipation device in FIG. 1A is disposed on a circuit board along a sectional line A-A′.

FIG. 2 is a schematic view illustrating that a heat dissipation device is disposed on a circuit board according to another embodiment of the disclosure.

FIG. 3 is a schematic top view illustrating that a heat dissipation device is disposed on a circuit board according to yet another embodiment of the disclosure.

### DESCRIPTION OF THE EMBODIMENTS

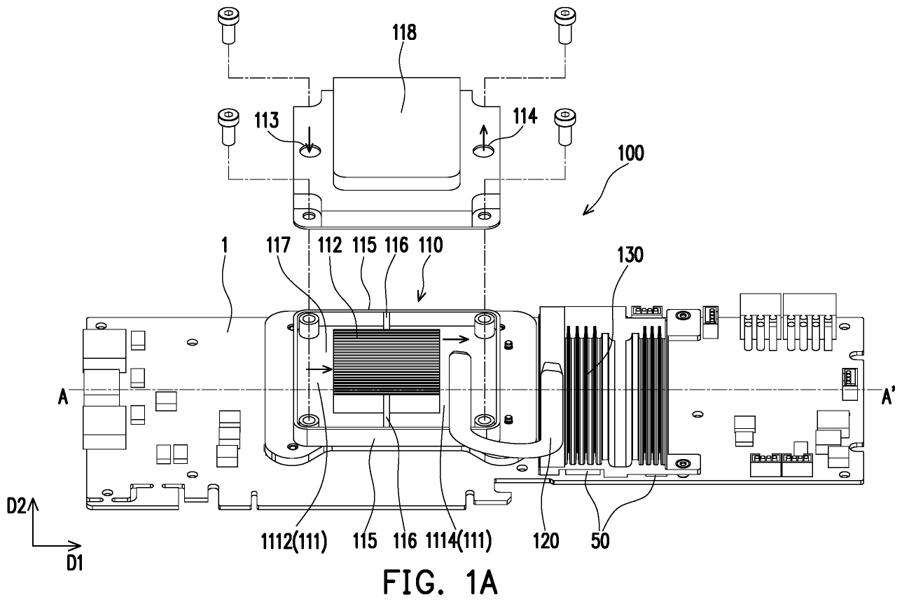

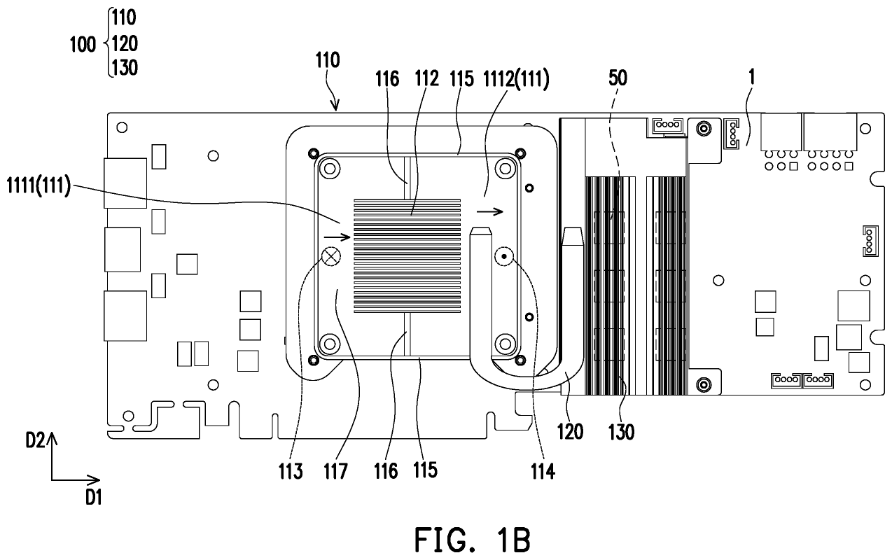

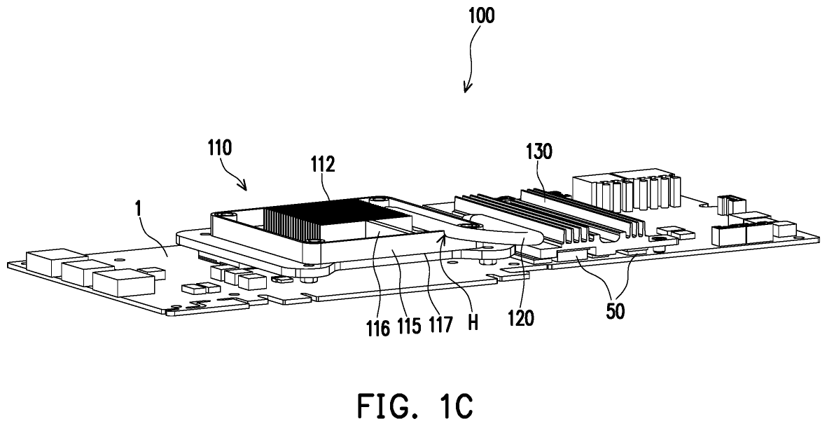

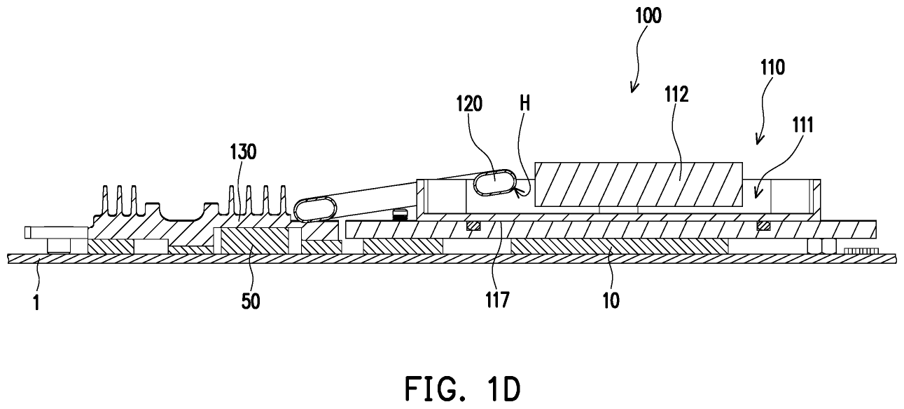

FIG. 1A is a schematic assembly view illustrating that a heat dissipation device disposed on a circuit board according to an embodiment of the disclosure. With reference to FIG. 1A, in the embodiment, a heat dissipation device 100 is adapted to be disposed on a primary heat source 10 (FIG. 1D) and a secondary heat source 50 and is configured to dissipate heat from the primary heat source 10 and the secondary heat source 50. According to the embodiment, note that the number of the primary heat source 10 shown in the drawings is one, for instance, and the number of the secondary heat source 50 shown in the drawings is plural; however, the number of the primary heat source 10 and the secondary heat source 50 should not be construed as a limitation in the disclosure.

It is worth mentioning that the heat dissipation device 100 provided in the disclosure is disposed on the circuit board 1 and is responsible for dissipating heat from the primary heat source 10 and the secondary heat source 50 on the circuit board 1. In the embodiment, the circuit board 1 is an expansion card, for instance, the primary heat source 10 is, for instance, a graphics processing unit (GPU), and the secondary heat source 50 is, for instance, a metal-oxide-semiconductor field-effect transistor (MOSFET) chip. Certainly, the heat source providing the heat dissipated by the heat dissipation device 100 is not limited in the disclosure, and the circuit board 1 may also be a motherboard. In addition, in order to clearly describe the internal structure of the heat dissipation device 100 of the disclosure, except for FIG. 1A, the structure of an upper cover 118 is omitted from the other figures.

FIG. 1B is a schematic top view illustrating that the heat dissipation device in FIG. 1A is disposed on a circuit board. With reference to FIG. 1A and FIG. 1B, in the embodiment, the heat dissipation device 100 includes a water cooling head module 110 and a heat conducting member 120. The water cooling head module 110 is disposed on the primary heat source 10, one portion of the heat conducting member 120 extends into the water cooling head module 110, and the other portion is thermally coupled to the secondary heat source 50 on the circuit board 1. Further, the primary heat source 10 provided in the embodiment is thermally coupled to the water cooling head module 110. Therefore, the heat energy generated by the primary heat source 10 is directly exported through the water cooling head module 110. In addition, the heat energy generated by the secondary heat source 50 provided in the embodiment may also be transmitted to the water cooling head module 110 through the heat conducting member 120 in a thermally conductive manner and also exported through the water cooling head module 110.

In view of said design, the heat dissipation device provided in the embodiment 100 may achieve the overall heat dissipation of the circuit board 1 through one water cooling head module 110. That is, the heat dissipation device 100 provided in the embodiment may simultaneously dissipate the heat from the primary heat source 10 (CPU) and the secondary heat source 50 (other components) in no need of occupying too much space.

Besides, as shown in FIG. 1A and FIG. 1B, the heat dissipation device provided in the embodiment 100 may also be equipped with a heat sink 130 on the secondary heat source 50, and the heat conducting member 120 is thermally coupled to the secondary heat source 50 through the heat sink 130. This design allows the heat sink 130 to simultaneously perform the heat conduction function and the function of dissipating the heat energy from the secondary heat source 50 to the air. Certainly, the type and the form of the heat sink are not limited in the disclosure, and it is not required for the secondary heat source 50 to have the heat sink 130 thereon. Alternatively, the heat sink 130 may be partially disposed on the secondary heat source 50, or the heat conducting member 120 may be directly thermally coupled to the secondary heat source 50.

As shown in FIG. 1A and FIG. 1B, the water cooling head module provided in the embodiment 110 has a water cooling tank 111, and the water cooling tank 111 includes the upper cover 118 (FIG. 1A). In detail, the water cooling tank 111 has an opening H (FIG. 1C) corresponding to the outer contour of the heat conducting member 120, and the shape of the heat conducting member 120 is a U shape according to the embodiment. Further, one section of the U-shaped heat conducting member 120 extends into the water cooling tank 111 through the opening H, and the other corresponding section of the U-shaped heat conducting member 120 is thermally coupled to the secondary heat source 50. Certainly, the shape of the heat conducting member 120 should not be construed as a limitation in the disclosure.

Further, in the present embodiment, there may be heat dissipation fluid inside the water cooling tank 111, for instance. Hence, an O-ring (not shown) is further disposed between the inner wall of the opening H (FIG. 1C) and the heat conducting member 120 of the embodiment to prevent leakage of the heat dissipation fluid. Certainly, the form of the O-ring is not limited in the disclosure; in other embodiments, other forms of anti-leakage structures or components may also be selected, and the disclosure is not limited thereto. According to the embodiment, although there is the heat dissipation fluid in the liquid form inside the water cooling tank 111, for instance, in other embodiments, the heat dissipation fluid may be two-phase fluid or other heat dissipation media in other non-liquid form. The type of the heat dissipation medium is not limited in the disclosure.

According to the embodiment, the heat conducting member 120 is a heat pipe. In detail, the heat pipe (the heat conducting member 120) is a closed cavity (not shown) containing two-phase fluid and dissipates heat through convection by the liquid and vapor changes of the two-phase fluid. Certainly, the form of the heat conducting member 120 is not limited in the disclosure.

Further, in the embodiment, the water cooling head module 110 includes a plurality of fins 112 disposed in the water cooling tank 111, and the fins 112 extend along a first direction D1 and are arranged in parallel along a second direction D2 on a bottom plate 117 of the water cooling tank 111. The bottom plate 117 of the water cooling tank 111 is coupled to the primary heat source 10. In the embodiment, the heat pipe is disposed beside the fins 112 and spaced apart from the fins 112 by a distance. Certainly, in other embodiments, the heat pipe may be adhered to the fins, or the fins 112 sleeve on the heat pipe, which should however not be construed as a limitation in the disclosure. Besides, in other embodiments, the arrangement manner of the fins 112 is not limited in the disclosure.

As shown in FIG. 1A and FIG. 1B, the water cooling head module 110 provided in the embodiment has a water outlet 114 and a water inlet 113 communicating with the water cooling tank 111. In FIG. 1, the water outlet 114 and the water inlet 113 provided in the embodiment are disposed at the upper cover 118 of the water cooling head module 110, and the heat dissipation fluid flows into and out of the water cooling tank 111 in a direction perpendicular to the upper cover 118. Certainly, the form and the location of the water outlet 114 and the water inlet 113 are not limited in the disclosure. In other embodiments, the water outlet 114 and the water inlet 113 may also be disposed on a side of the water cooling tank 111 or may be designed in other appropriate manner, which should not be construed as a limitation in the disclosure.

In detail, as shown in FIG. 1B, in the embodiment, the water cooling head module 110 includes at least one side wall 115 and at least one inner partition board 116. For instance, in the embodiment, the number of the side walls 115 is four, and the number of the inner partition boards 116 is two. Two of the four side walls 115 extend along the first direction D1 and are located at opposite sides of the fins 112, and the two inner partition boards 116 extend along the second direction D2 and are connected to the two side walls 115 and two outermost fins of the fins 112. In addition, the water inlet 113 is located at one side of a line connecting the two side walls 115, and the water outlet 114 is located at the other side of the line.

Further, in the embodiment, the water cooling tank 111 includes a first region 1112 and a second region 1114. Specifically, the water inlet 113 communicates with the first region 1112, and the water outlet 114 communicates with the second region 1114. The first region 1112 and the second region 1114 are partitioned by the inner partition board 116, and the fins 112 extend from the first region 1112 to the second region 1114. Thereby, the heat dissipation fluid flows into the first region 1112 through the water inlet 113, flows into the second region 1114 through the fins 112, and then flows out of the water outlet 114.

Certainly, in other embodiments, the inner partition boards 116 may also be disposed at other locations, or the water cooling tank 111 may be equipped with one or no inner partition board 116. For instance, in an embodiment, one side of the fins 112 may directly lean against one of the side walls 115, and the inner partition boards 116 are connected to the other side (the outermost side) of the fins 112 and the corresponding side walls 115.

Alternatively, in another embodiment, the fins 112 may also be arranged in parallel from one of the side walls 115 (e.g., the side wall 115 on the upper portion of FIG. 1B) to the other side wall 115 (e.g., the side wall 115 on the lower portion of FIG. 1B) along the second direction D2, the water outlet 114 and the water inlet 113 are arranged along the first direction D1 at both terminals of the fins 112. Thereby, the water cooling head module 110 does not need to be equipped with any inner partition board 116, and the heat dissipation fluid may still flow through the fins 112. Certainly, the disclosure is not limited thereto, given that the fluid can flow toward the water outlet 114 through the fins 112 to ensure the good heat dissipation effects. Moreover, the number of the side walls 115, the number of the inner partition boards 116, the location of the inner partition boards 116, and the location of the fins 112 are not limited in the disclosure.

FIG. 1C is a schematic view illustrating that the heat dissipation device in FIG. 1A is disposed on a circuit board at another view angle. FIG. 1D is a schematic partial cross-sectional view illustrating that the heat dissipation device in FIG. 1A is disposed on a circuit board along a sectional line A-A′. As shown in FIG. 1C and FIG. 1D, the opening H of the water cooling tank 111 in the embodiment is higher than the bottom plate 117 of the water cooling tank 111. In other words, there is a certain distance between the edge of the opening H and the bottom plate 117. Hence, when the heat conducting member 120 is disposed on the opening H, the heat conducting member 120 is suspended from the bottom plate 117. As such, the heat dissipation fluid may flow through the bottom surface of the heat conducting member 120, so as to increase the heat dissipation efficiency. Certainly, in other embodiments, the heat conducting member 120 may also directly contact the bottom plate 117, and the relative location of the heat conducting member 120 and the bottom plate 117 is not limited in the disclosure.

According to the embodiment, it is worth mentioning that the water cooling head module 110 of the heat dissipation device 100 may adopt a standard design, and the shape and the length of the heat conducting member 120 may be adjusted according to the location of the secondary heat source 50 generated heat to be dissipated by the heat conducting member 120. Designers may select a specific heat conducting member 120 matching the water cooling head module 110 of uniform size according to the location of the secondary heat source 50 on different circuit boards 1. As such, the heat dissipation device 100 can have a good cost-performance ratio, and it is not necessary to make mold to produce specific heat dissipation device 100 tailored for the corresponding circuit board 1.

Other embodiments are provided below for explanation. The same or similar structural configurations, design principles, and technical effects in each embodiment are not further explained, but the design differences between the embodiments will be mainly described.

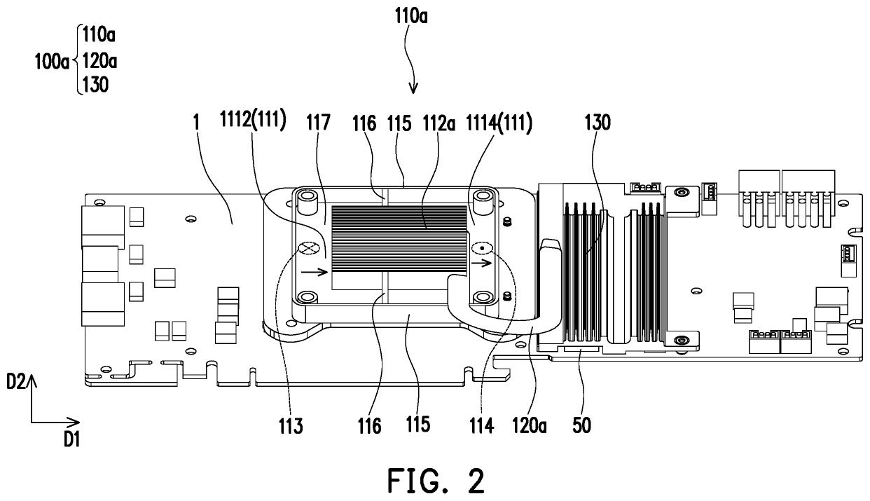

FIG. 2 is a schematic view illustrating that a heat dissipation device is disposed on a circuit board according to another embodiment of the disclosure. With reference to FIG. 2, the main difference between the heat dissipation device 100a provided in the embodiment and the heat dissipation device 100 provided in the previous embodiment lies in that in the fins 112a of the water cooling head module 110a sleeve on one portion of the heat conducting member 120a (the heat pipe) along the second direction D2. As such, when the heat dissipation fluid flows through the fins 112a, most of the heat dissipation fluid inevitably flows through the heat conducting member 120a, so that the conduction efficiency of the heat conducting member 120a may be increased.

Note that that some of the fins 112a on the right side (in the direction of FIG. 2) may sleeve on the heat conducting member 120a shown in FIG. 2. Certainly, in other embodiments, the fins 112 (in the direction of FIG. 2) in the middle or on the left side may sleeve on the heat conducting member 120, which should not be construed as a limitation in the disclosure.

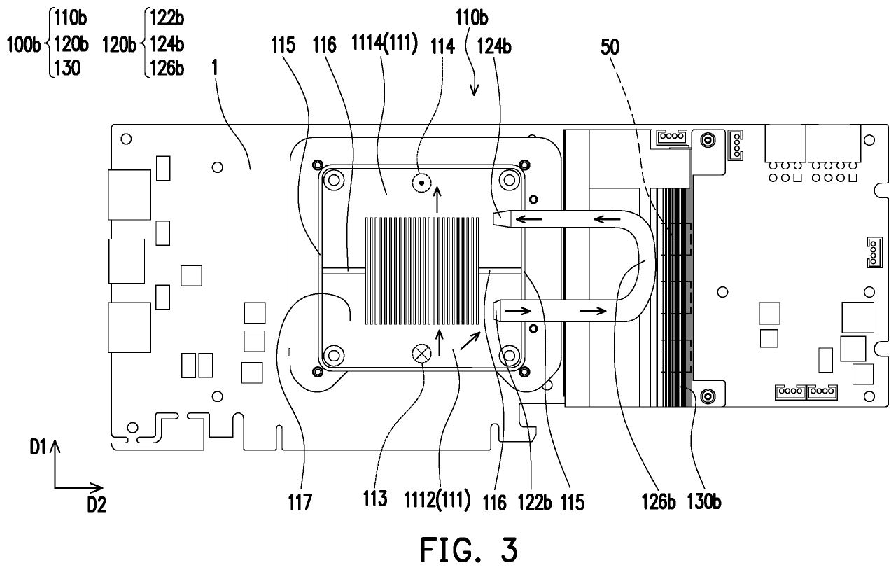

FIG. 3 is a schematic top view illustrating that a heat dissipation device is disposed on a circuit board according to yet another embodiment of the disclosure. With reference to FIG. 3, the main difference between the heat dissipation device provided in the embodiment 100b and the heat dissipation device provided in the previous embodiment lies in that the heat conducting member 120b in the embodiment is a hollow runner pipe. That is, the heat dissipation fluid in the water cooling tank 111b of the water cooling head module 110b provided in the embodiment may be circulated in the heat conducting member (the runner pipe) 120b and the water cooling tank 111b.

In detail, according to the embodiment, the heat conducting member 120b (the runner pipe) has a first terminal 122b, a second terminal 124b opposite to the first terminal 122b, and a middle segment 126b located between the first terminal 122b and the second terminal 124b. Further, the middle segment 126b of the heat conducting member 120b (the runner pipe) is thermally coupled to the secondary heat source 50, the first terminal 122b of the heat conducting member 120b (the runner pipe) extends into and communicates with the first region 1112 of the water cooling tank 111, and the second terminal 124b extends into and communicates with the second region 1114 of the water cooling tank 111. Thereby, the heat dissipation fluid may flow from the first region 1112 into the first terminal 122b of the heat conducting member 120b (the runner pipe) through the middle segment 126b and then flow from the second terminal 124b to the second region 1114, so as to bring the heat of the secondary heat source 50 to the second region 1114 of the water cooling tank 111b.

Moreover, in the embodiment, an inner diameter of the first terminal 122b of the heat conducting member 120b (the runner pipe) is larger than an inner diameter of the second terminal 124b. As shown in FIG. 3, the inner diameter of the heat conducting member 120b (the runner pipe) extending from the first terminal 122b to the middle segment 126b thermally coupled the secondary heat source 50 is greater than the inner diameter of the heat conducting member 120b (the runner pipe) extending from the middle segment 126b thermally coupled to the secondary heat source 50 to the second terminal 124b. Thereby, the flow resistance of the first terminal 122b of the heat conducting member 120b (the runner pipe) may be smaller than the flow resistance of the second terminal 124b, so that the flow direction of the heat dissipation fluid is from the first region 1112 to the second region 1114, thereby preventing the heat dissipation fluid from flowing back and affecting the heat dissipation efficiency. Through the design of the hollow pipe, the heat conducting member 120b (the runner pipe) provided in the embodiment allows the heat dissipation fluid to flow through a wider region, so as to efficiently dissipate the heat generated by the primary heat source 10 and the secondary heat source on the entire circuit board 1.

In addition, in the embodiment, the heat conducting member 120b (the runner pipe) is, for instance, a hollow copper pipe. Certainly, in other embodiments, the material of the runner pipe may be another thermally conductive metal material or another non-metallic thermally conductive material, which should not be construed as a limitation in the disclosure.

To sum up, the heat dissipation device provided in one or more embodiments of the disclosure includes the water cooling head module and the heat conducting member. The water cooling head module is thermally coupled to the primary heat source, one portion of the heat conducting member extends into the water cooling head module, and the other portion is thermally coupled to the secondary heat source. Thereby, the heat dissipation device provided in one or more embodiments of the disclosure dissipates heat from plural heat sources at the same time with use of one water cooling head module. In other words, the heat dissipation device provided in one or more embodiments of the disclosure may achieve heat dissipation effects within a limited space in a more efficient manner and may be more extensively applied. On the other hand, the fins provided in one or more embodiments of the disclosure may directly sleeve on the heat conducting member, or the heat dissipation fluid may flow to the secondary heat source through the fins, so that the water cooling head module provided herein may achieve favorable heat dissipation.

It will be apparent to those skilled in the art that various modifications and variations can be made to the disclosed embodiment without departing from the scope or spirit of the disclosure. In view of the foregoing, it is intended that the disclosure covers modifications and variations provided that they fall within the scope of the following claims and their equivalents.

What is claimed is:

1. A heat dissipation device adapted to be disposed on a primary heat source and a secondary heat source and comprising:
a water cooling head module disposed on the primary heat source; and
a heat conducting member thermally coupled to the secondary heat source and extending into the water cooling head module.

2. The heat dissipation device according to claim 1, wherein the water cooling head module has a water cooling tank and a plurality of fins, the plurality of fins extend along a first direction and are arranged in parallel along a second direction in the water cooling tank, and the plurality of fins sleeve on one portion of the heat conducting member along the second direction.

3. The heat dissipation device according to claim 2, wherein the heat conducting member comprises a heat pipe.

4. The heat dissipation device according to claim 1, wherein the water cooling head module has a water cooling tank, a water inlet, a water outlet, and a plurality of fins, the water inlet and the water outlet are respectively connected to the water cooling tank, the plurality of fins extend along a first direction and arranged in parallel along a second direction in the water cooling tank, the water cooling head module comprises at least one side wall and at least one inner partition board, the at least one side wall extends along the first direction and is located on at least one side of the plurality of fins, and the at least one inner partition board extends along the second direction and is connected to the at least one side wall and at least one outermost fin of the plurality of fins.

5. The heat dissipation device according to claim 4, wherein the at least one side wall comprises two side walls, the at least one inner partition board comprises two inner partition boards, the two side walls extend along the first direction and are located on both sides of the plurality of fins, the two inner partition boards extend along the second direction and are connected to the two side walls and two outermost fins of the plurality of fins, the water inlet is located at one side of a line connecting the two side walls, and the water outlet is located at the other side of the line connecting the two side walls.

6. The heat dissipation device according to claim 1, wherein the water cooling head module has a water cooling tank, a water inlet, a water outlet, and a plurality of fins, the water cooling tank comprises a first region and a second region, the water inlet is connected to the first region, the water outlet is connected to the second region, the plurality of fins extend from the first region to the second region, the heat conducting member has a first terminal, a second terminal opposite to the first terminal, and a middle segment located between the first terminal and the second terminal, the middle segment is thermally coupled to the secondary heat source, the first terminal extends into and communicates with the first region of the water cooling tank, and the second terminal extends into and communicates with the second region of the water cooling tank.

7. The heat dissipation device according to claim 6, wherein the heat conducting member is a runner pipe, and an inner diameter of the first terminal is greater than an inner diameter of the second terminal.

8. The heat dissipation device according to claim 1, further comprising a heat sink disposed on the secondary heat source, the heat conducting member being thermally coupled to the secondary heat source through the heat sink.

9. The heat dissipation device according to claim 1, wherein the water cooling head module further comprises a bottom plate disposed on the primary heat source, and the heat conducting member contacts the bottom plate.

10. The heat dissipation device according to claim 1, wherein the water cooling head module further comprises a bottom plate disposed on the primary heat source, and the heat conducting member is suspended from the bottom plate.
